(19) United States
(12) Patent Application Publication
(10) Pub. No.: US 2021/0328189 A1
(43) Pub. Date: Oct. 21, 2021

(54) PACKAGING METHOD AND PACKAGING STRUCTURE OF PANEL, AND DISPLAY DEVICE COMPRISING PACKAGING STRUCTURE THEREOF

(71) Applicant: Shenzhen China Star Optoelectronics Semiconductor Display Technology Co., Ltd., Shenzhen, Guangdong (CN)

(72) Inventors: Xianglong LI, Shenzhen, Guangdong (CN); Iguchi SINSUKE, Shenzhen, Guangdong (CN)

(21) Appl. No.: 16/620,904

(22) PCT Filed: Nov. 14, 2019
(86) PCT No.: PCT/CN2019/118470

§ 371 Date: Dec. 10, 2019

(51) Int. Cl. H01L 51/52

(52) U.S. Cl. CPC H01L 51/5259; H01L 51/5246

(57) ABSTRACT

The present invention provides a packing method of a panel. The packing method of the panel includes following steps of: providing a substrate having an OLED light emitting device; coating a sealant around the OLED light emitting device; applying a water-oxygen absorber between the sealant and the OLED light emitting device; and aligning the substrate to cover a packaging glass cover for curing. Wherein, the water-oxygen absorber covers or partially covers a redundant pixel region of the OLED light emitting device to effectively reduce a width of a frame of the panel.

### FIELD OF INVENTION

The present invention relates to the field of display technologies, and in particular, to a packaging method and a packaging structure of a panel, and a display device comprising the packaging structure.

### BACKGROUND OF INVENTION

Organic light emitting diode (OLED) panels are an important direction for research and development of display devices, and have achieved remarkable results in applications such as small sizes and large sizes.

However, in structures of OLED panels manufactured by inkjet printing technologies, redundant pixel regions with certain widths are generally required, so that an OLED light emitting device 120 can be uniformly formed within a film. Therefore, a frame of an inkjet printing panel generally at least comprises a circuit trace, a redundant pixel region, a packaging region, and the like.

Therefore, as shown in FIG. 1, a panel comprises a display region 210 and a non-display region 220 disposed around the display region 210. The display region 210 includes the OLED light emitting device 120 and a redundant pixel region 160, and the non-display region 220 includes a connection trace region. This will make a frame of the panel too wide to achieve a narrow frame of the panel.

Therefore, there is a need to provide a packaging method and a packaging structure of a panel, and a display device comprising the packaging structure to solve problems existing in the prior art.

### Technical Problem

Current panels comprise a display region and a non-display region disposed around the display region. There are an OLED light emitting device and a redundant pixel region in the display region, and a connection trace region in the non-display region. This will make a frame of the panel too wide to achieve a narrow frame of the panel.

### Technical Solution

In order to solve the above technical problem, an object of the present invention is to provide a packaging method and a packaging structure of a panel, and a display device comprising the packaging structure, in which a water-oxygen absorber and a redundant pixel region are all covered or partially covered and shared to reduce a width of a frame of the panel.

In order to achieve the above object, the present invention provides a packaging method of a panel. The packaging method of the panel comprises following steps of: providing a substrate having an OLED light emitting device; coating a sealant around the OLED light emitting device; applying a water-oxygen absorber between the sealant and the OLED light emitting device; and aligning the substrate to cover a packaging glass cover for curing; wherein the water-oxygen absorber covers or partially covers a redundant pixel region of the OLED light emitting device.

In an embodiment of the present invention, a distance between the sealant and an edge of the redundant pixel region of the OLED light emitting device is between 0.1 mm and 10 mm, a width of the sealant is between 0.1 mm and 3 mm, and a height of the sealant is between 3 um and 60 um.

In an embodiment of the present invention, a distance between the water-oxygen absorber and the sealant is 0 mm to 3 mm, a width of the water-oxygen absorber is between 1 mm to 5 mm, and a height of the water-oxygen absorber is between 3 μm to 60 μm.

In an embodiment of the present invention, the curing step consists of curing by ultraviolet rays in an ultraviolet curing machine.

In an embodiment of the present invention, a curing condition of the curing step is: an energy density of the ultraviolet light is between 3000 mJ/cm² and 5000 mJ/cm², and an irradiation time of the ultraviolet light is between 30 seconds and 100 seconds.

In an embodiment of the present invention, a main component of the sealant is acrylic resin.

In order to achieve the above object, the present invention further provides a packaging structure of a panel. The packaging structure of the panel comprises a substrate; an OLED light emitting device disposed on the substrate; a sealant coated around the OLED light emitting device; a water-oxygen absorber disposed between the sealant and the OLED light emitting device; and a packaging glass cover, aligning and covering the substrate; wherein the water-oxygen absorber covers or partially covers a redundant pixel region of the OLED light emitting device.

In an embodiment of the present invention, a distance between the sealant and an edge of the redundant pixel region of the OLED light emitting device is between 0.1 mm and 10 mm, a width of the sealant is between 0.1 mm and 3 mm, and a height of the sealant is between 3 um and 60 um.

In an embodiment of the present invention, a distance between the water-oxygen absorber and the sealant is 0 mm to 3 mm, a width of the water-oxygen absorber is between 1 mm to 5 mm, and a height of the water-oxygen absorber is between 3 μm to 60 μm.

In an embodiment of the present invention, a main component of the sealant is acrylic resin.

In order to achieve the above object, the present invention further provides a display device. The display device comprises the packaging structure of the panel.

### Beneficial Effect

The present invention provides a packaging method and a packaging structure of a panel, and a display device comprising the packaging structure, in which a water-oxygen absorber and a redundant pixel region are all covered or partially covered and shared. Therefore, a covered or partially covered region can effectively reduce a width of a frame of the panel to achieve a high screen ratio and a narrow frame.

### DESCRIPTION OF DRAWINGS

FIG. 1 shows a schematic view of a packaging structure according to a prior art.

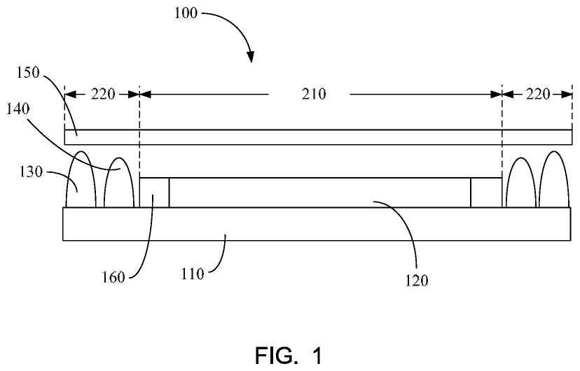

FIG. 2 shows a flowchart of a packaging method of a panel according to the present invention.

FIG. 3 shows a schematic structural view of a first embodiment of the packaging method of the panel according to the present invention.

FIG. 4 shows a schematic structural view of a second embodiment of the packaging method of the panel according to the present invention.

### DETAILED DESCRIPTION OF PREFERRED EMBODIMENTS

The above and other objects, features, and advantages of the present invention will become more apparent from the understanding of the appended claims. Furthermore, the directional terms mentioned in the present invention, such as up, down, top, bottom, front, back, left, right, inner, outer, side, surrounding, center, horizontal, horizontal, vertical, longitudinal, axial, radial, uppermost or lowermost, etc., only refer to the direction of the additional schema. Therefore, the directional terminology used is for the purpose of illustration and understanding of the disclosure rather than limiting the disclosure.

In the drawings, units with similar structures are denoted by the same reference numerals.

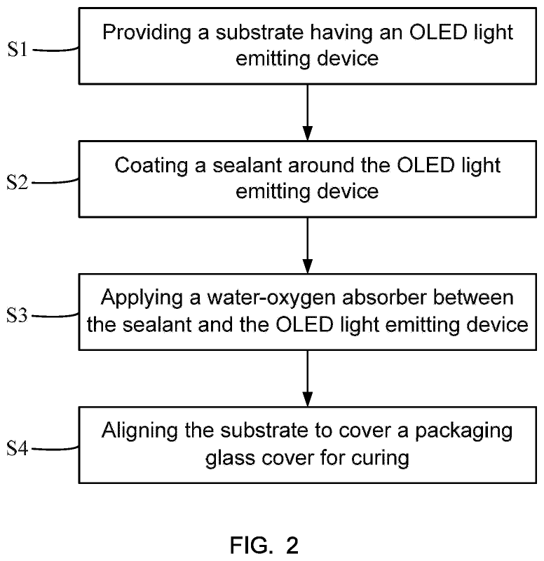

FIG. 2 shows a flowchart of a packaging method of a panel according to the present invention.

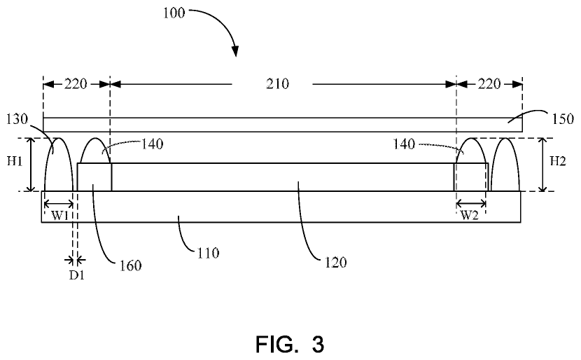

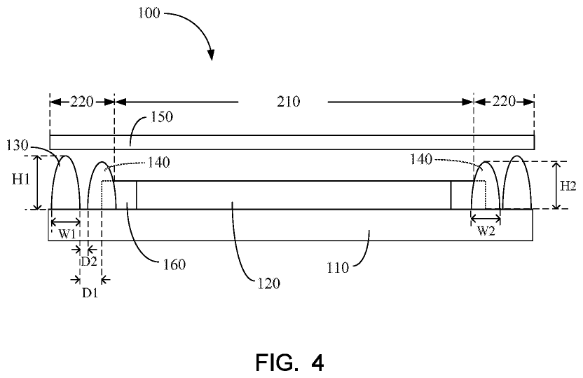

Referring to FIG. 3 and FIG. 4 together, a schematic flowchart of the packaging method of the panel in the present invention comprises: S1: providing a substrate 110 having an OLED light emitting device 120; S2: coating a sealant 130 around the OLED light emitting device 120; S3: applying a water-oxygen absorber 140 between the sealant 130 and the OLED light emitting device 120; and S4: aligning the substrate 110 to cover a packaging glass cover 150 for curing. Wherein, the water-oxygen absorber 140 covers or partially covers a redundant pixel region 160 of the OLED light emitting device 120, thereby effectively reducing an overall width of a frame of the panel.

By providing the water-oxygen absorber 140 covering or partially covering and sharing the redundant pixel region 160, the packaging method and the packaging structure of the panel, and a display device comprising the packaging structure of the embodiment can effectively reduce the width of the frame of the panel, and achieve technical effects of a high screen ratio and a narrow frame.

As shown in FIG. 3 and FIG. 4, the present invention further provides a packaging structure 100 of a panel. The packaging structure 100 comprises: a substrate 110, an OLED light emitting device 120, a sealant 130, a water-oxygen absorber 140, and a packaging glass cover 150.

The OLED light emitting device 120 is disposed on the substrate 110. The sealant 130 is coated around the OLED light emitting device 120. The water-oxygen absorber 140 is disposed between the sealant 130 and the OLED light emitting device 120. The packaging glass cover 150 aligns and covers the substrate 110. Wherein, the water-oxygen absorber 140 covers or partially covers a redundant pixel region 160 of the OLED light emitting device 120.

In detail, as shown in a first embodiment of FIG. 3, the water-oxygen absorber 140 covers or partially covers the redundant pixel region 160 of the OLED light emitting device 120. At this time, a distance D1 between the sealant 130 and an edge of the redundant pixel region 160 of the OLED light emitting device 120 is between 0.1 mm and 10 mm. In other words, in the first embodiment, a distance D2 between the sealant 130 and the water-oxygen absorber 140 is also between 0.1 mm and 10 mm.

Preferably, in the first embodiment, a width W1 of the sealant 130 is between 0.1 mm and 3 mm, and a height H1 of the sealant 130 is between 3 um and 60 um. A width W2 of the water-oxygen absorber 140 is between 1 mm and 5 mm, and a height H2 of the water-oxygen absorber 140 is between 3 μm and 60 μm.

Therefore, when the water-oxygen absorber 140 is disposed on the redundant pixel region 160 of the OLED light-emitting device 120 in a fully covered manner, a size of the display region 210 can be effectively increased relative to the prior art, and a size of the non-display region 220 is reduced.

On the other hand, as shown in a second embodiment according to FIG. 4, the water-oxygen absorber 140 is disposed on the redundant pixel region 160 of the OLED light emitting device 120 in a partially covered manner. At this time, the distance D1 between the sealant 130 and the edge of the redundant pixel region 160 of the OLED light emitting device 120 is between 0.1 mm and 10 mm, and the distance D2 between the water-oxygen absorber 140 and the sealant 130 is between 0 mm and 3 mm.

Preferably, in the second embodiment, the width W1 of the sealant 130 is between 0.1 mm and 3 mm, and the height H1 of the sealant 130 is between 3 um and 60 um. The width W2 of the water-oxygen absorber 140 is between 1 mm and 5 mm, and the height H2 of the water-oxygen absorber 140 is between 3 μm and 60 μm.

Therefore, when the water-oxygen absorber 140 is disposed on the redundant pixel region 160 of the OLED light-emitting device 120 in a partially covered manner, the size of the display region 210 can be effectively increased relative to the prior art, and the size of the non-display region 220 is reduced.

In the present invention, the curing step consists of curing by ultraviolet in an ultraviolet curing machine. A curing condition of the curing step is: an energy density of the ultraviolet light is between 3000 mJ/cm² and 5000 mJ/cm², and an irradiation time of the ultraviolet light is between 30 seconds and 100 seconds.

In the present invention, a main component of the sealant is acrylic resin.

The present invention further comprises a display device comprising the packaging structure 100 of the panel. The display device can be a liquid crystal display device, a light emitting diode display device, or the like.

As mentioned above, since the present invention can provide the packaging method and the packaging structure of the panel, and the display device comprising the packaging structure, in which the water-oxygen absorber 140 covers or partially covers and shares the redundant pixel region 160, the covered or partially covered region can thus effectively reduce the width of the frame of the panel, and achieve objectives of a high screen ratio and a narrow frame.

The present invention has been shown and described with respect to one or more implementations, and equivalents and modifications will be apparent to those skilled in the art. The present invention includes all such modifications and variations, and is only limited by the scope of the claims. With particular regard to the various functions performed by the above-described components, the terms used to describe such components are intended to correspond to any component (unless otherwise indicated) that performs the specified functions (for example, it is functionally equivalent) of the components, even if it is structurally not identical to the disclosed structure for performing the functions in the exemplary implementation of the present specification shown herein. Moreover, although specific features of the specification have been disclosed with respect to only one of several implementations, such features may be combined with one or more other implementations as may be desired and advantageous for a given or particular application.

In the above, various other corresponding changes and modifications can be made according to the technical solutions and technical ideas of the present invention to those skilled in the art, and all such changes and modifications are within the scope of the claims of the present invention.

What is claimed is:

1. A packaging method of a panel, comprising following steps of:
providing a substrate having an OLED light emitting device;
coating a sealant around the OLED light emitting device;
applying a water-oxygen absorber between the sealant and the OLED light emitting device; and
aligning the substrate to cover a packaging glass cover for curing;
wherein the water-oxygen absorber covers or partially covers a redundant pixel region of the OLED light emitting device.

2. The packaging method of the panel as claimed in claim 1, wherein a distance between the sealant and an edge of the redundant pixel region of the OLED light emitting device is between 0.1 mm and 10 mm, a width of the sealant is between 0.1 mm and 3 mm, and a height of the sealant is between 3 um and 60 um.

3. The packaging method of the panel as claimed in claim 2, wherein a distance between the water-oxygen absorber and the sealant is between 0 mm and 3 mm, a width of the water-oxygen absorber is between 1 mm and 5 mm, and a height of the water-oxygen absorber is between 3 μm and 60 μm.

4. The packaging method of the panel as claimed in claim 1, wherein the curing step consists of curing by ultraviolet in an ultraviolet curing machine.

5. The packaging method of the panel as claimed in claim 4, wherein a curing condition of the curing step is: an energy density of the ultraviolet is between 3000 mJ/cm² and 5000 mJ/cm², and an irradiation time of the ultraviolet is between 30 seconds and 100 seconds.

6. The packaging method of the panel as claimed in claim 1, wherein a main component of the sealant is acrylic resin.

7. A packaging structure of a panel, comprising:
a substrate;
an OLED light emitting device disposed on the substrate;
a sealant coated around the OLED light emitting device;
a water-oxygen absorber disposed between the sealant and the OLED light emitting device; and
a packaging glass cover, aligning and covering the substrate;
wherein the water-oxygen absorber covers or partially covers a redundant pixel region of the OLED light emitting device.

8. The packaging structure of the panel as claimed in claim 7, wherein a distance between the sealant and an edge of the redundant pixel region of the OLED light emitting device is between 0.1 mm and 10 mm, a width of the sealant is between 0.1 mm and 3 mm, and a height of the sealant is between 3 um and 60 um.

9. The packaging structure of the panel as claimed in claim 8, wherein a distance between the water-oxygen absorber and the sealant is between 0 mm and 3 mm, a width of the water-oxygen absorber is between 1 mm and 5 mm, and a height of the water-oxygen absorber is between 3 μm and 60 μm.

10. A display device, comprising:
the packaging structure of the panel as claimed in claim 7.
